(19) United States
(12) Patent Application Publication
(10) Pub. No.: US 2024/0071808 A1
(43) Pub. Date: Feb. 29, 2024

(54) METHODS FOR FORMING SEMICONDUCTOR DEVICES WITH ISOLATION STRUCTURES

(71) Applicant: Tokyo Electron Limited, Tokyo (JP)

(72) Inventors: Hojin Kim, Albany, NY (US); Mingmei Wang, Albany, NY (US); Soo Doo Chae, Albany, NY (US)

(73) Assignee: Tokyo Electron Limited, Tokyo (JP)

(21) Appl. No.: 17/898,104

(22) Filed: Aug. 29, 2022

(51) Int. Cl. H01L 21/762; H01L 21/306

(52) U.S. Cl. CPC H01L 21/76224; H01L 21/306

(57) ABSTRACT

A method for forming a semiconductor device is disclosed. The method includes forming a first layer on a substrate. The method includes forming a second layer on the first layer. The substrate and the second layer have a first semiconductor material and the first layer has a second semiconductor material, and an etching selectivity is present between the first semiconductor material and the second semiconductor material. The method includes performing a first etching process to remove a portion of the second layer until the first layer is exposed, wherein the first layer is configured as an etch stop layer for the first etching process.

### FIELD OF THE DISCLOSURE

This disclosure relates generally to isolation structures for semiconductor processing and in particular to methods for manufacturing isolation structures with high aspect ratio geometries.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### SUMMARY

At least one aspect of the present disclosure is directed to a method for forming a semiconductor device. The method includes forming a first layer on a substrate. The method includes forming a second layer on the first layer. The substrate and the second layer have a first semiconductor material and the first layer has a second semiconductor material, and an etching selectivity is present between the first semiconductor material and the second semiconductor material. The method includes performing a first etching process to remove a portion of the second layer until the first layer is exposed, wherein the first layer is configured as an etch stop layer for the first etching process.

In some embodiments, the first semiconductor material includes silicon, and the second semiconductor material includes silicon germanium. Further, a molar ratio of germanium of the second semiconductor material is equal to or greater than 1/2.

In some embodiments, a ratio of the etching selectivity is equal to or greater than 1/100.

In some embodiments, prior to performing the first etching process, the method further includes forming a layer stack over the second layer, wherein the layer stack includes a plurality of third layers and a plurality of fourth layers alternately stacked on top of one another, and wherein the plurality of third layers each have the first semiconductor material and the plurality of fourth layers each have a third semiconductor material; and performing a second etching process to remove a portion of the layer stack, wherein the removed portion of the layer stack is vertically aligned with the removed portion of the second layer.

In some embodiments, subsequently to performing the first etching process, the method further includes performing a third etching process to remove a portion of the first layer, wherein the removed portion of the first layer is vertically aligned with the removed portion of the second layer. The method further includes filling the removed portion of the second layer and the removed portion of the first layer with a dielectric material thereby forming an isolation structure. The isolation structure is configured to electrically isolate remaining portions of the layer stack that are disposed on opposite sides of the removed portion of the layer stack.

In some embodiments, the first semiconductor material includes silicon, the second semiconductor material includes first silicon germanium with a first germanium molar ratio, and the third semiconductor material includes second silicon germanium with a second germanium molar ratio. In some embodiments, the first germanium molar ratio is substantially greater than the second germanium molar ratio.

At least another aspect of the present disclosure is directed to a method for forming a semiconductor device. The method includes forming, on a substrate having a first semiconductor material, a first layer having a second semiconductor material. The method includes overlaying the first layer with a second layer having the first semiconductor material. The method includes forming a layer stack over the second layer. The layer stack includes a plurality of third layers and a plurality of fourth layers alternately stacked on top of one another, and wherein the plurality of third layers each have the first semiconductor material and the plurality of fourth layers each have a third semiconductor material. The method includes etching a portion of the layer stack until the second layer is exposed. The method includes etching, through at least the etched portion of the layer stack, a portion of the second layer until the first layer is exposed.

In some embodiments, the method further includes etching, through at least the etched portion of the layer stack and the etched portion of the second layer, a portion of the first layer until a top surface of the substrate is exposed; and filling the etched portion of the second layer and the etched portion of the first layer with a dielectric material thereby forming an isolation structure.

In some embodiments, the method further includes etching, through at least the etched portion of the layer stack and the etched portion of the second layer, a portion of the first layer and a portion of the substrate until an intermediate surface of the substrate is exposed; and filling the etched portion of the second layer, the etched portion of the first layer, and the etched portion of the substrate with a dielectric material thereby forming an isolation structure.

In some embodiments, the first semiconductor material includes silicon, the second semiconductor material includes first silicon germanium with a first germanium molar ratio, and the third semiconductor material includes second silicon germanium with a second germanium molar ratio. The first germanium molar ratio is substantially greater than the second germanium molar ratio.

In some embodiments, the first layer is configured as an etch stop layer during etching the portion of the second layer.

In some embodiments, an etching selectivity is present between the first semiconductor material and the second semiconductor material, and wherein a ratio of the etching selectivity is equal to or greater than 1/100.

Yet another aspect of the present disclosure is directed to a method for forming a semiconductor device. The method includes forming one or more etch stop layers having a second semiconductor material embedded in a first semiconductor material. The method includes defining an active region of a transistor on the first semiconductor material. The method includes etching first portions of the first semiconductor material disposed above at least one of the one or more etch stop layers and on opposite sides of the active region, respectively, until the at least one etch stop layer is exposed. The method includes forming an isolation structure by filling at least the etched first portions of the first semiconductor material with a dielectric material.

In some embodiments, the first semiconductor material includes silicon, and the second semiconductor material includes silicon germanium. Further, a molar ratio of germanium of the second semiconductor material is equal to or greater than 1/2.

These and other aspects and implementations are discussed in detail below. The foregoing information and the following detailed description include illustrative examples of various aspects and implementations, and provide an overview or framework for understanding the nature and character of the claimed aspects and implementations. The drawings provide illustrations and a further understanding of the various aspects and implementations, and are incorporated in and constitute a part of this specification. Aspects can be combined, and it will be readily appreciated that features described in the context of one aspect of the invention can be combined with other aspects. Aspects can be implemented in any convenient form. As used in the specification and in the claims, the singular form of “a,” “an,” and “the” include plural referents unless the context clearly dictates otherwise.

### BRIEF DESCRIPTION OF THE DRAWINGS

Non-limiting embodiments of the present disclosure are described by way of example with reference to the accompanying figures, which are schematic and are not intended to be drawn to scale. Unless indicated as representing the background art, the figures represent aspects of the disclosure. For purposes of clarity, not every component may be labeled in every drawing. In the drawings:

FIG. 1 illustrates a flow chart of a method for forming a semiconductor device using a metal shell hard mask, in accordance with various embodiments.

FIGS. 2-10 illustrate cross-sectional views of a semiconductor device, made by the method shown in FIG. 1, during various stages of fabrication, in accordance with various embodiments.

FIGS. 11-15 illustrate cross-sectional views of another semiconductor device, made by the method shown in FIG. 1, during various stages of fabrication, in accordance with various embodiments.

### DETAILED DESCRIPTION

Reference will now be made to the illustrative embodiments depicted in the drawings, and specific language will be used here to describe the same. It will nevertheless be understood that no limitation of the scope of the claims or this disclosure is thereby intended. Alterations and further modifications of the inventive features illustrated herein, and additional applications of the principles of the subject matter illustrated herein, which would occur to one skilled in the relevant art and having possession of this disclosure, are to be considered within the scope of the subject matter disclosed herein. Other embodiments may be used and/or other changes may be made without departing from the spirit or scope of the present disclosure. The illustrative embodiments described in the detailed description are not meant to be limiting of the subject matter presents.

In integrated circuit manufacturing processes, devices such as transistors are formed along the surfaces of semiconductor chips. In general, the devices are electrically isolated from each other by one or more isolation regions/structures. Shallow Trench Isolation (STI) structures are commonly used as such isolation structures to electrically isolate respective active regions of the devices. Typically, STI structures are formed of a dielectric material or dielectric materials filled into trenches in semiconductor substrates.

As a density of the devices formed over the semiconductor substrate becomes ever higher, forming the corresponding trenches has become increasingly challenging. For example, even though all trenches should have a similar depth, some of the trenches may have an insufficient depth (sometimes referred to as “pitch-walking”). This can cause some of the later formed STI structures to have insufficient dielectric material being filled, which can disadvantageously result in leakage from the devices that are supposed to be isolated from those STI structures. As such, the existing methods for forming isolation structures have not been entirely satisfactory in some aspects.

The present disclosure provides various embodiments of methods for forming isolation structures of a semiconductor device. In some embodiments, the semiconductor device may include a number of transistors, each of which may be configured in any of various transistor structures (e.g., gate-all-around (GAA) transistor structures, FinFET structures, channel-all-around (CAA) transistor structures, etc.), formed over a substrate. The isolation structures, formed by the method as disclosed herein, can have a uniform geometry to efficiently isolate the transistors, even being formed in a high integration density. For example, some of the current embodiments rely on forming one or more silicon germanium layers embedded in a silicon material. Such silicon germanium layers may have a substantially high germanium molar ratio (e.g., equal to or greater than 50%), which allows each of these silicon germanium layers to serve as an etch stop layer when forming corresponding trenches for the isolation structures. With the disclosed etch stop layers embedded in the silicon material (at least a portion of which may form a substrate), the corresponding etching process can be advantageously allowed to last more. As such, even if an aspect ratio (depth to width) of some of the trenches is high, the etching process can be allowed to fully form those trenches, while maintaining geometries of other trenches (as the etching process can be spontaneously stopped by the etch stop layers).

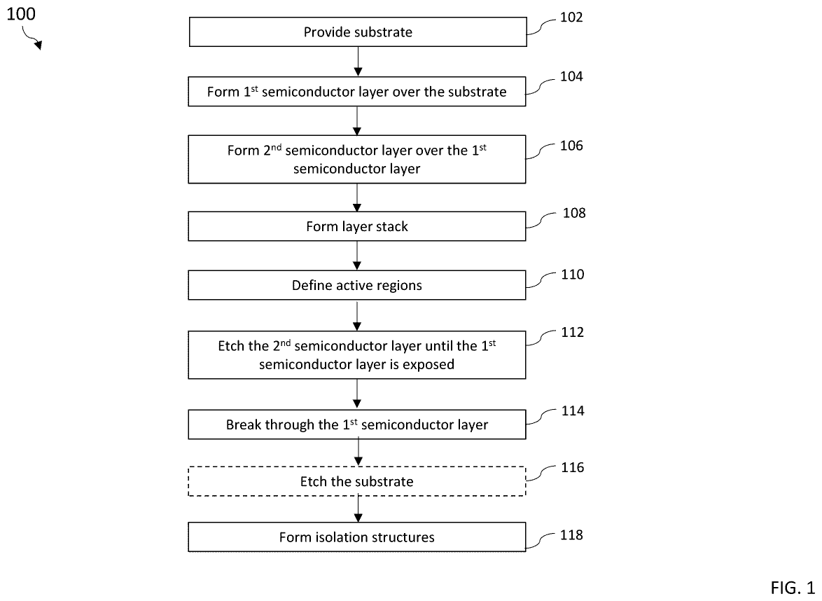

FIG. 1 illustrates a flowchart of a method 100 to form isolation structures for a transistor structure, according to one or more embodiments of the present disclosure. For example, at least some of the operations (or steps) of the method 100 can be used to form isolation structures that can electrically isolate neighboring devices in a FinFET structure, a GAA transistor structure, a CAA transistor structure, a vertical transistor structure, or the like. It is noted that the method 100 is merely an example, and is not intended to limit the present disclosure. Accordingly, it is understood that additional operations may be provided before, during, and after the method 100 of FIG. 1, and that some other operations may only be briefly described herein.

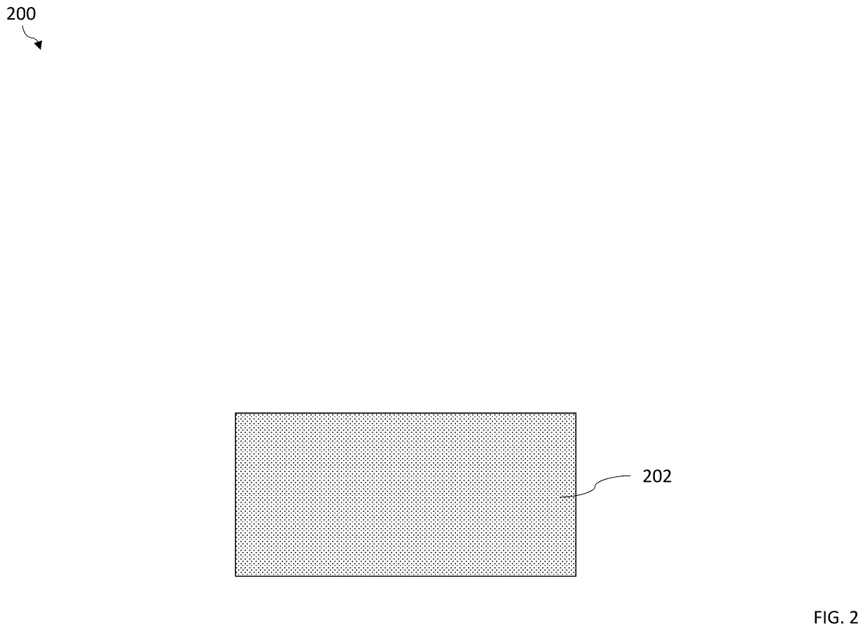

In some embodiments, operations of the method 100 may be associated with cross-sectional views of an example semiconductor device 200 (e.g., a portion of a GAA transistor structure) at various fabrication stages as shown in FIGS. 2-10, respectively, which will be discussed in further detail below. It should be understood that the semiconductor device 200 shown in FIGS. 2-10 is not a completed GAA transistor structure for the purposes of brevity. For example, the following figures of the semiconductor device 200 do not include source/drain structures coupled to opposite sides of each of the channels or a gate electrode wrapping around each of the channels.

Corresponding to operation 102 of FIG. 1, FIG. 2 is a cross-sectional view of the GAA transistor structure 200 including a semiconductor substrate 202 at one of the various stages of fabrication. In some embodiments, the cross-sectional view of FIG. 2 may be cut in a direction perpendicular to the lengthwise direction of one or more channels of the GAA transistor structure 200 (e.g., the lengthwise direction of an active/dummy gate structure of the GAA transistor structure 200).

The substrate 202 may be a semiconductor substrate, such as a bulk semiconductor, a semiconductor-on-insulator (SOI) substrate, or the like, which may be doped (e.g., with a p-type or an n-type dopant) or undoped. In some embodiments, the substrate 202 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. For example, the semiconductor material of the substrate 202 may include silicon; a compound semiconductor including silicon carbide, gallium arsenic, gallium phosphide, indium phosphide, indium arsenide, and/or indium antimonide; an alloy semiconductor including, GaAsP, AlInAs, AlGaAs, GaInAs, GaInP, and/or GaInAsP; or combinations thereof.

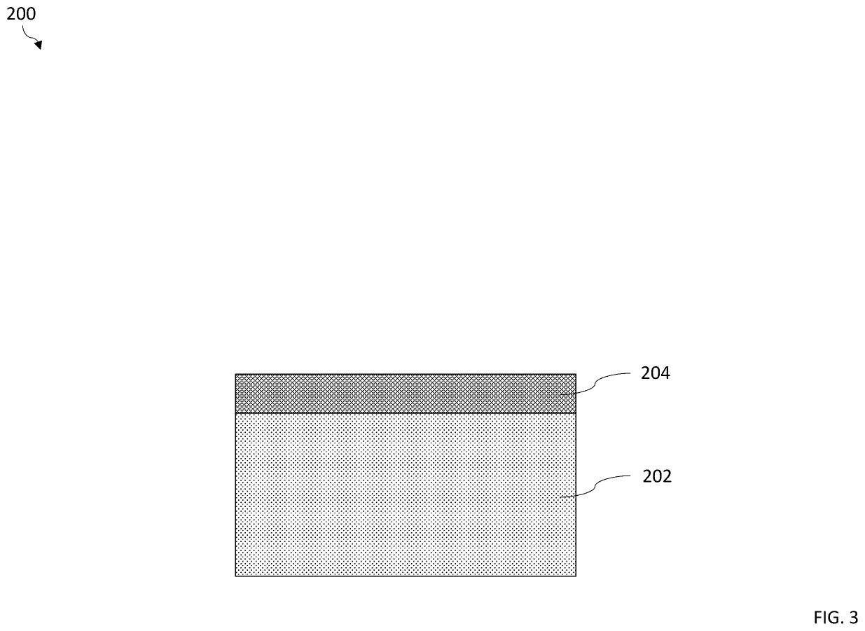

Corresponding to operation 104 of FIG. 1, FIG. 3 is a cross-sectional view of the GAA transistor structure 200 including a first semiconductor layer 204 disposed over the semiconductor substrate 202 at one of the various stages of fabrication. In some embodiments, the cross-sectional view of FIG. 3 may be cut in a direction perpendicular to the lengthwise direction of one or more channels of the GAA transistor structure 200 (e.g., the lengthwise direction of an active/dummy gate structure of the GAA transistor structure 200).

In some embodiments, the first semiconductor layer 204 essentially consists of a semiconductor material different from the material of the substrate 202. Further, an etch selectivity equal to or higher than 1/100 is present between the materials of the first semiconductor layer 204 and the substrate 202. For example, in the case where a material of the substrate 202 is silicon, a material of the first semiconductor layer 204 is silicon germanium (Si₁₋ₓGeₓ) that includes equal to or greater than 50% (x>0.5) Ge in molar ratio. The first semiconductor layer 204 may be epitaxially grown from the substrate 202. For example, the first semiconductor layer 204 may be grown by a molecular beam epitaxy (MBE) process, a chemical vapor deposition (CVD) process such as a metal organic CVD (MOCVD) process, and/or other suitable epitaxial growth processes.

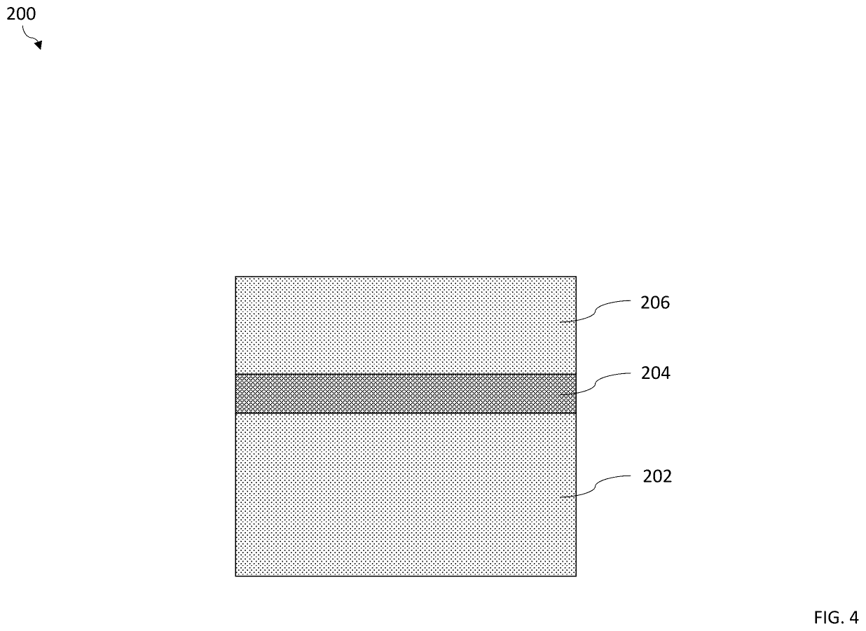

Corresponding to operation 106 of FIG. 1, FIG. 4 is a cross-sectional view of the GAA transistor structure 200 including a second semiconductor layer 206 disposed over the first semiconductor layer 204 at one of the various stages of fabrication. In some embodiments, the cross-sectional view of FIG. 4 may be cut in a direction perpendicular to the lengthwise direction of one or more channels of the GAA transistor structure 200 (e.g., the lengthwise direction of an active/dummy gate structure of the GAA transistor structure 200).

In some embodiments, the second semiconductor layer 206 may essentially consist of a material substantially similar to the substrate 202. For example, a material of the second semiconductor layer 206 is silicon. As such, the high germanium ratio of silicon germanium of the first semiconductor layer 204 may be “embedded” in silicon of the substrate 202 and second semiconductor layer 206. According to various embodiments of the present disclosure, at least partially due to the etch selectivity between the respective materials, the first semiconductor layer 204 may function as an etch stop layer during etching the second semiconductor layer 206. Further, the depth of a trench by etching at least the second semiconductor layer 206 (i.e., the height of a corresponding isolation structure) may be determined based on a thickness of the second semiconductor layer 206. The thickness of the second semiconductor layer 206 can even be flexibly adjusted, since the etch process on the second semiconductor layer 206 can be spontaneously stopped by the first semiconductor layer 204. The second semiconductor layer 206 may be epitaxially grown from the first semiconductor layer 204. For example, the second semiconductor layer 206 may be grown by a molecular beam epitaxy (MBE) process, a chemical vapor deposition (CVD) process such as a metal organic CVD (MOCVD) process, and/or other suitable epitaxial growth processes.

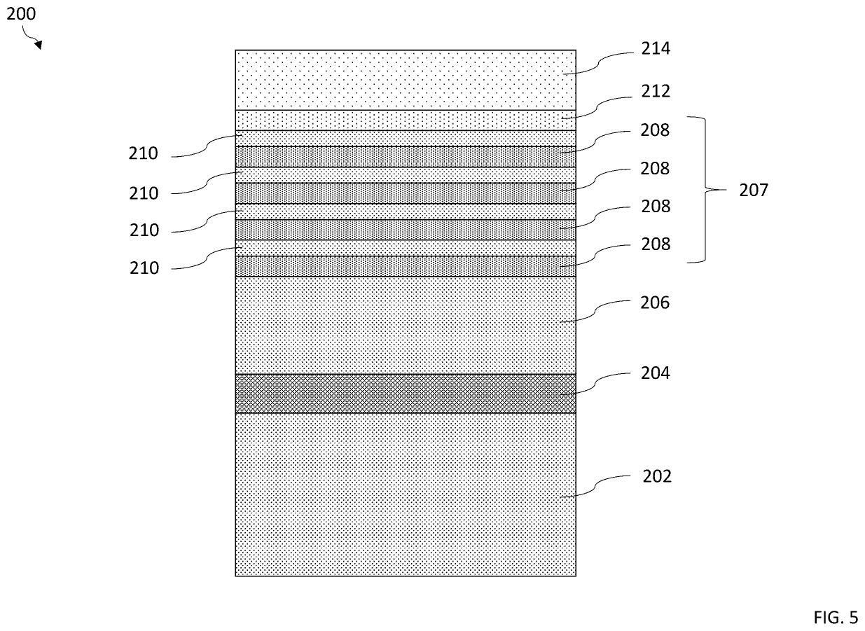

Corresponding to operation 108 of FIG. 1, FIG. 5 is a cross-sectional view of the GAA transistor structure 200 including a layer stack 207 disposed over the second semiconductor layer 206 at one of the various stages of fabrication. In some embodiments, the cross-sectional view of FIG. 5 may be cut in a direction perpendicular to the lengthwise direction of one or more channels of the GAA transistor structure 200 (e.g., the lengthwise direction of an active/dummy gate structure of the GAA transistor structure 200).

As shown, the layer stack 207 includes a number of third semiconductor layers 208 and a number of fourth semiconductor layers 210 alternatingly disposed on top of one another along a vertical direction. As will be discussed below, the third semiconductor layers 208 may be later removed or replaced with the wrapping gate structure of a GAA transistor and the fourth semiconductor layers 210 may collectively function as the channel of a GAA transistor. Accordingly, the third semiconductor layers 208 and fourth semiconductor layers 210 are sometimes referred to as “sacrificial layers 208” and “channel layers 210,” respectively. For example in FIG. 5, one of the fourth semiconductor layers 210 is disposed over one of the third semiconductor layers 208 then another one of the third semiconductor layers 208 is disposed over the fourth semiconductor layer 210, so on and so forth.

The semiconductor layers 208 and 210 may have respective different thicknesses. Further, the third semiconductor layers 208 may have different thicknesses from one layer to another layer. The fourth semiconductor layers 210 may have different thicknesses from one layer to another layer. The thickness of each of the semiconductor layers 208 and 210 may range from few nanometers to few tens of nanometers. In some embodiments, the bottommost layer of the stack 207 may be thicker than other semiconductor layers 208 and 210. In an embodiment, each of the third semiconductor layers 208 has a thickness ranging from about 5 nanometers (nm) to about 20 nm, and each of the fourth semiconductor layers 210 has a thickness ranging from about 5 nm to about 20 nm.

The third and fourth semiconductor layers 208 and 210 have different compositions. In various embodiments, the semiconductor layers 208 and 210 have compositions that provide for different oxidation rates and/or different etch selectivity between the layers. In an embodiment, the third semiconductor layers 208 each include silicon germanium (Si₁₋ₓGeₓ), and the fourth semiconductor layers 210 each include silicon (Si). In an embodiment, each of the semiconductor layers 210 is silicon that may be undoped or substantially dopant-free (i.e., having an extrinsic dopant concentration from about 0 cm⁻³ to about 1×10¹⁷ cm⁻³), where for example, no intentional doping is performed when being forming. Each of the semiconductor layers 208 is Si₁₋ₓGeₓ that includes less than 50% (x<0.5) Ge in molar ratio. For example, Ge may comprise about 15% to 35% of the semiconductor layers 208 of Si₁₋ₓGeₓ in molar ratio. Furthermore, the third semiconductor layers 208 may include different compositions among them, and the fourth semiconductor layers 210 may include different compositions among them.

Either of the semiconductor layers 208 and 210 may include other materials, for example, a compound semiconductor such as silicon carbide, gallium arsenide, gallium phosphide, indium phosphide, indium arsenide, and/or indium antimonide, an alloy semiconductor such as GaAsP, AlInAs, AlGaAs, InGaAs, GaInP, and/or GaInAsP, or combinations thereof. The materials of the semiconductor layers 208 and 210 may be chosen based on providing differing oxidation rates and/or etch selectivity.

The semiconductor layers 208 and 210 can be epitaxially grown from the second semiconductor layer 206. For example, each of the semiconductor layers 208 and 210 may be grown by a molecular beam epitaxy (MBE) process, a chemical vapor deposition (CVD) process such as a metal organic CVD (MOCVD) process, and/or other suitable epitaxial growth processes. During the epitaxial growth, the crystal structure of the second semiconductor layer 206 can extend upwardly, resulting in the semiconductor layers 208 and 210 having the same or similar crystal orientation with the second semiconductor layer 206.

Upon forming the stack 207, the stack 207 may be patterned to form one or more active regions (e.g., fin structures), which will be discussed in the next operation 110 of the method 100. For example, a mask layer (which can include multiple layers such as, for example, a pad oxide layer 212 and an overlying pad nitride layer 214) is formed over the topmost semiconductor layer (e.g., 210 in FIG. 5). The pad oxide layer 212 may be a thin film comprising silicon oxide formed, for example, using a thermal oxidation process. The pad oxide layer 212 may act as an adhesion layer between the topmost semiconductor layer 210 and the overlying pad nitride layer 214. In some embodiments, the pad nitride layer 214 is formed of silicon nitride, silicon oxynitride, silicon carbonitride, the like, or combinations thereof. The pad nitride layer 214 may be formed using low-pressure chemical vapor deposition (LPCVD) or plasma enhanced chemical vapor deposition (PECVD), for example.

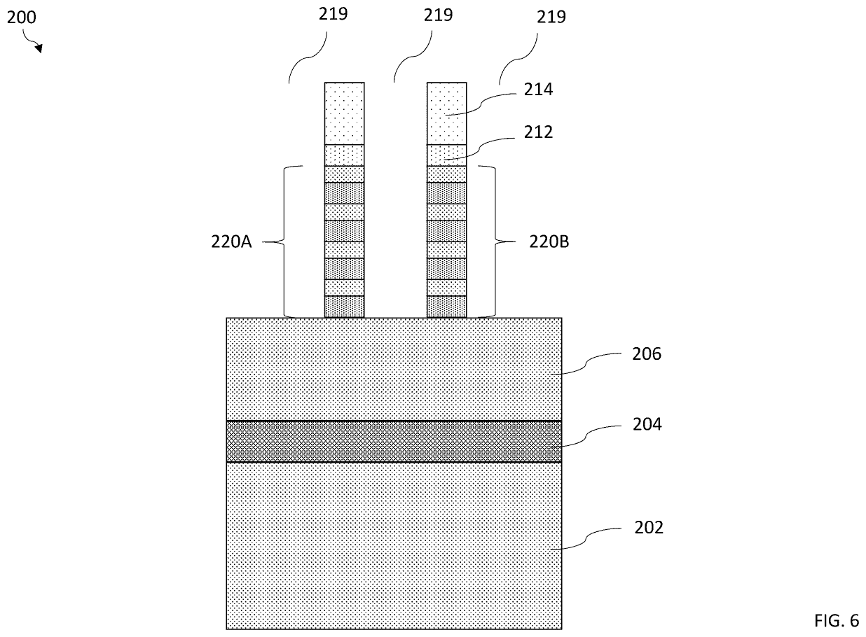

Corresponding to operation 110 of FIG. 1, FIG. 6 is a cross-sectional view of the GAA transistor structure 200 in which a number of active regions, e.g., 220A and 220B, are defined, at one of the various stages of fabrication. In some embodiments, the cross-sectional view of FIG. 6 may be cut in a direction perpendicular to the lengthwise direction of one or more channels of the GAA transistor structure 200 (e.g., the lengthwise direction of an active/dummy gate structure of the GAA transistor structure 200).

The mask layer (212 and 214) may be patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer 212 and pad nitride layer 214 to form a patterned mask.

The patterned mask can be subsequently used to pattern exposed portions of the semiconductor layers 208 and 210 to form trenches (or openings) 219, thereby defining the active regions (e.g., fin structures) 220A and 220B between adjacent trenches. When multiple fin structures are formed, such a trench may be disposed between any adjacent ones of the fin structures. In some embodiments, the fin structures 220A and 220B are formed by etching trenches in the semiconductor layers 208 and 210 using, for example, reactive ion etch (ME), neutral beam etch (NBE), the like, or combinations thereof. The etch may be anisotropic. The etch may stop at the second semiconductor layer 206. In some embodiments, the trenches 219 may be strips (when viewed from the top) parallel to each other, and closely spaced with respect to each other. In some embodiments, the trenches 219 may each be continuous and surround a corresponding one of the fin structure 220A-B.

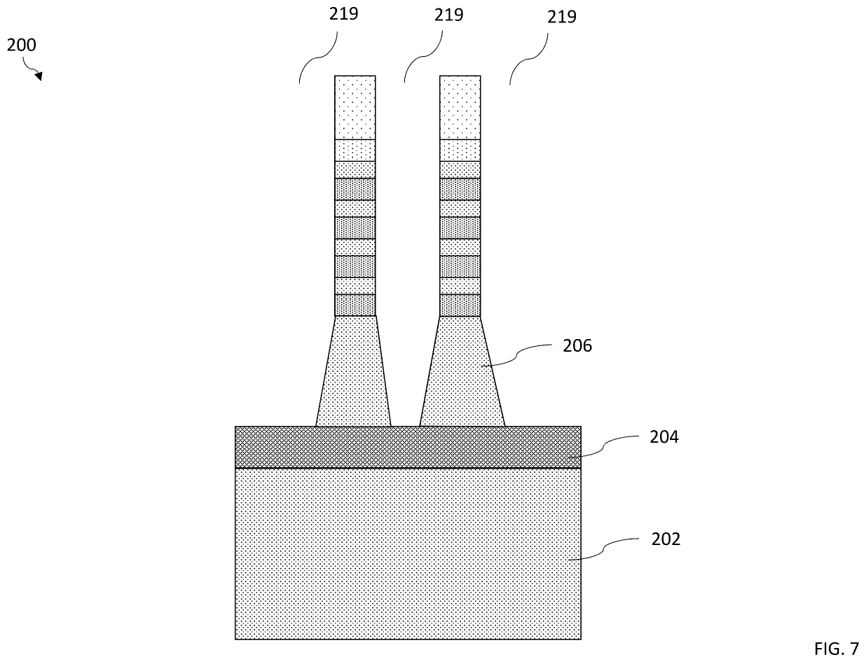

Corresponding to operation 112 of FIG. 1, FIG. 7 is a cross-sectional view of the GAA transistor structure 200 in which the second semiconductor layer 206 is etched until the first semiconductor layer 204 is exposed, at one of the various stages of fabrication. In some embodiments, the cross-sectional view of FIG. 7 may be cut in a direction perpendicular to the lengthwise direction of one or more channels of the GAA transistor structure 200 (e.g., the lengthwise direction of an active/dummy gate structure of the GAA transistor structure 200).

The trenches 219 may be further extended into the substrate 202 by etching the second semiconductor layer 206. According to various embodiments of the present disclosure, when etching the second semiconductor layer 206, the first semiconductor layer 204 may serve as an etch stop layer. Alternative stated, the etch process of the second semiconductor layer 206 can be stopped once the first semiconductor layer 204 is exposed. This is due to the relatively high etch selectivity between the second semiconductor layer 206 and the first semiconductor layer 204. In the above example where the second semiconductor layer 206 is formed of silicon and the first semiconductor layer 204 is formed of silicon germanium with high germanium molar ratio (e.g., about 50%, Si_{0.5}Ge_{0.5}), a ratio of the etch selectivity can be around 1/100. It is thus understood that the materials of the second semiconductor layer 206 and the first semiconductor layer 204 should not be limited to silicon and this particular ratio of silicon germanium or even silicon germanium, respectively. For example, the materials of the second semiconductor layer 206 and the first semiconductor layer 204 can be any of various other different semiconductor materials with high enough etch selectivity, while remaining within the scope of the present disclosure.

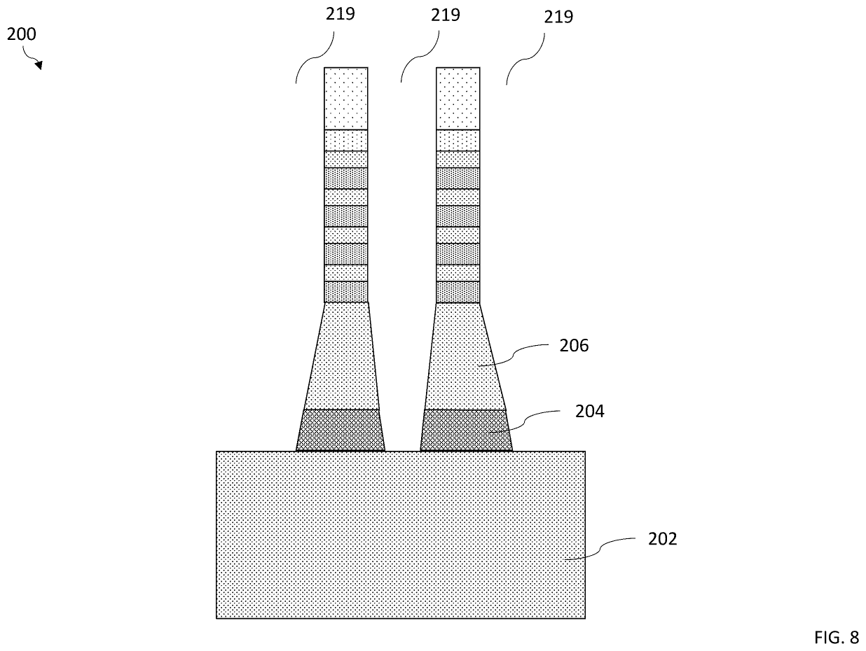

Corresponding to operation 114 of FIG. 1, FIG. 8 is a cross-sectional view of the GAA transistor structure 200 in which the first semiconductor layer 204 is broken through until the substrate 202 is exposed, at one of the various stages of fabrication. In some embodiments, the cross-sectional view of FIG. 8 may be cut in a direction perpendicular to the lengthwise direction of one or more channels of the GAA transistor structure 200 (e.g., the lengthwise direction of an active/dummy gate structure of the GAA transistor structure 200).

Following extending through the second semiconductor layer 206, yet another etch process can be performed to break through the etch stop layer, e.g., the first semiconductor layer 204, so as to further extend the trenches 219. Such an etch process can be stopped upon the substrate 202 being exposed.

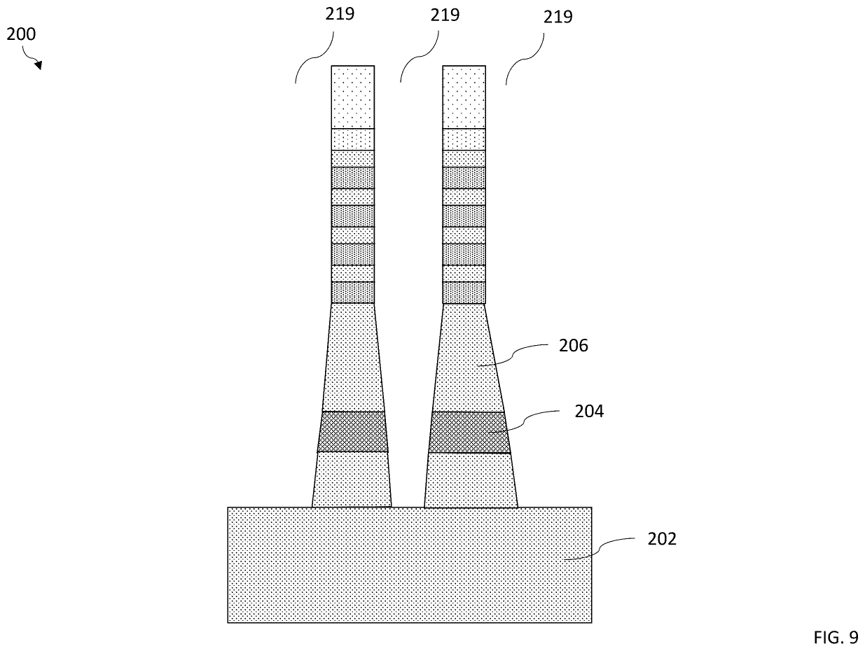

Corresponding to optional operation 116 of FIG. 1, FIG. 9 is a cross-sectional view of the GAA transistor structure 200 in which the substrate 202 is etched, at one of the various stages of fabrication. In some embodiments, the cross-sectional view of FIG. 8 may be cut in a direction perpendicular to the lengthwise direction of one or more channels of the GAA transistor structure 200 (e.g., the lengthwise direction of an active/dummy gate structure of the GAA transistor structure 200).

In some embodiments, the trenches 219 can be further extended by recessing the substrate 202 (through yet another etch process). As such, the height of an isolation structure (which will be later formed by filling a portion of each trench 219) may be determined based on respective thicknesses of the second semiconductor layer 206, the first semiconductor layer 204, and the recessed portion of substrate 202. In some other embodiments, upon breaking through the etch stop layer (e.g., the first semiconductor layer 204), the trenches 219 may not be further extended. As such, the height of an isolation structure (which will be later formed by filling a portion of each trench 219) may be determined based on respective thicknesses of the second semiconductor layer 206 and the first semiconductor layer 204.

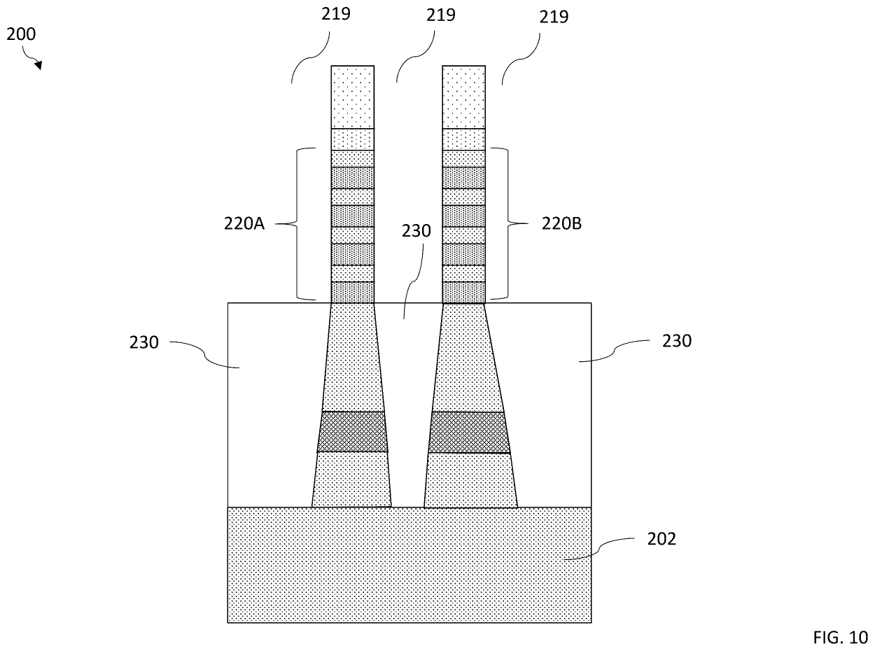

Corresponding to optional operation 118 of FIG. 1, FIG. 10 is a cross-sectional view of the GAA transistor structure 200 including a number of isolation structures 230 at one of the various stages of fabrication. In some embodiments, the cross-sectional view of FIG. 10 may be cut in a direction perpendicular to the lengthwise direction of one or more channels of the GAA transistor structure 200 (e.g., the lengthwise direction of an active/dummy gate structure of the GAA transistor structure 200).

The isolation structures 230 can be formed by filling respective lower portions of the trenches 219. As such, the isolation structures 230 may each be formed between adjacent fin structures 220A and 220B, or next to a single fin structure 220A or 220B. The isolation structures 230, which are formed of an insulation material, can electrically isolate neighboring fin structures from each other. The insulation material may be an oxide, such as silicon oxide, a nitride, the like, or combinations thereof, and may be formed by a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other insulation materials and/or other formation processes may be used. In an example, the insulation material is silicon oxide formed by a FCVD process. An anneal process may be performed once the insulation material is formed. A planarization process, such as a chemical mechanical polish (CAR′) process, may remove any excess insulation material and form a top surface of the insulation material and a top surface of the patterned mask. The patterned mask may also be removed by the planarization process, in some embodiments.

Next, the insulation material is recessed to form the isolation structure 230, as shown in FIG. 10, which is sometimes referred to as a shallow trench isolation (STI) structure. The isolation structure 230 is recessed such that the fin structure 220A/B protrudes from between neighboring portions of the isolation structure 230. The top surface of the isolation structures 230 may have a flat surface (as illustrated), a convex surface, a concave surface (such as dishing), or combinations thereof. The top surface of the isolation structure 230 may be formed flat, convex, and/or concave by an appropriate etch. The isolation structure 230 may be recessed using an acceptable etching process, such as one that is selective to the material of the isolation structure 230. For example, a dry etch or a wet etch using dilute hydrofluoric (DHF) acid may be performed to recess the isolation structure 230.

As mentioned above, the operations of method 100 shown in FIG. 1 do not form a completed GAA transistor structure. To further form a GAA transistor structure, at least some of the following operations can be performed on the GAA transistor structure 200 shown in FIG. 10. For example, following forming the isolation structures 230, a dummy gate structure can be formed to straddle the fin structures 220A-B. As such, the dummy gate structure and the fin structures 220A-B can have their lengthwise directions perpendicular to each other. Next, source/drain structures can be epitaxially formed on opposite sides of the dummy gate structure (along the lengthwise direction of the fin structures 220A-B). Next, the dummy gate structure and the first semiconductor layers 208 can be replaced with an active (e.g., metal) gate structure that wraps around each of the second semiconductor layers 210 of the fin structures 220A-B.

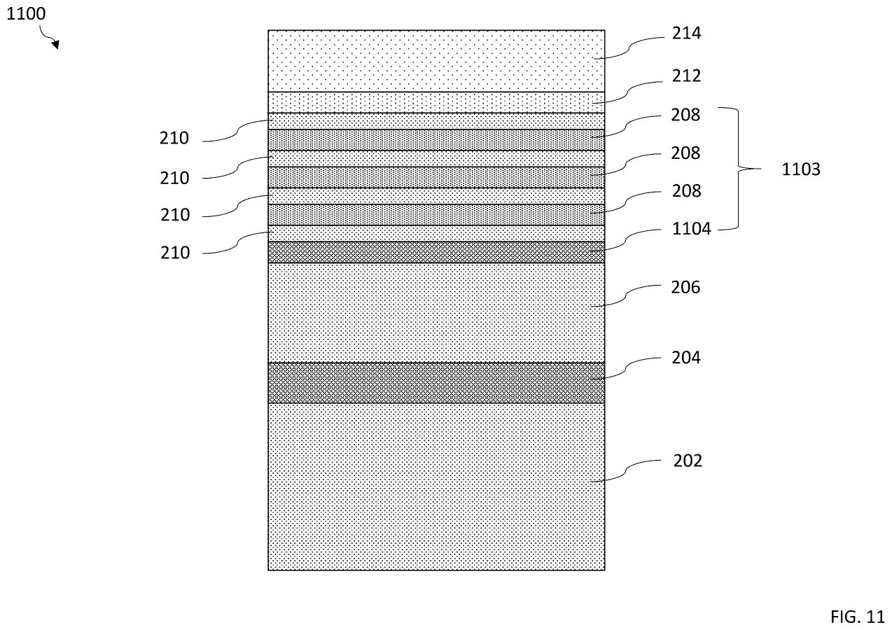

FIG. 11 to FIG. 15 illustrate cross-sectional views of another GAA transistor structure 1100 that can be also formed by the method 100 of FIG. 1 (without operation 116), at various fabrication stages, respectively. Thus, the reference numerals above are continued to be used for similar features of the GAA transistor structure 1100.

Referring first to FIG. 11, which corresponds to operation 108 (FIG. 1), a stack 1103 is also formed above the second semiconductor layer 206, which is formed over the first semiconductor layer 204 that functions as an etch stop layer for the etch process on the second semiconductor layer 206. Different from the stack 207, the stack 1103 further includes a semiconductor layer 1104 interposed between the bottommost fourth semiconductor layer 210 and the second semiconductor layer 206. The semiconductor layer 1104 may be similar to the third semiconductor layer 208, but with a different germanium molar ratio (e.g., higher than the germanium molar ratio of the third semiconductor layer 208).

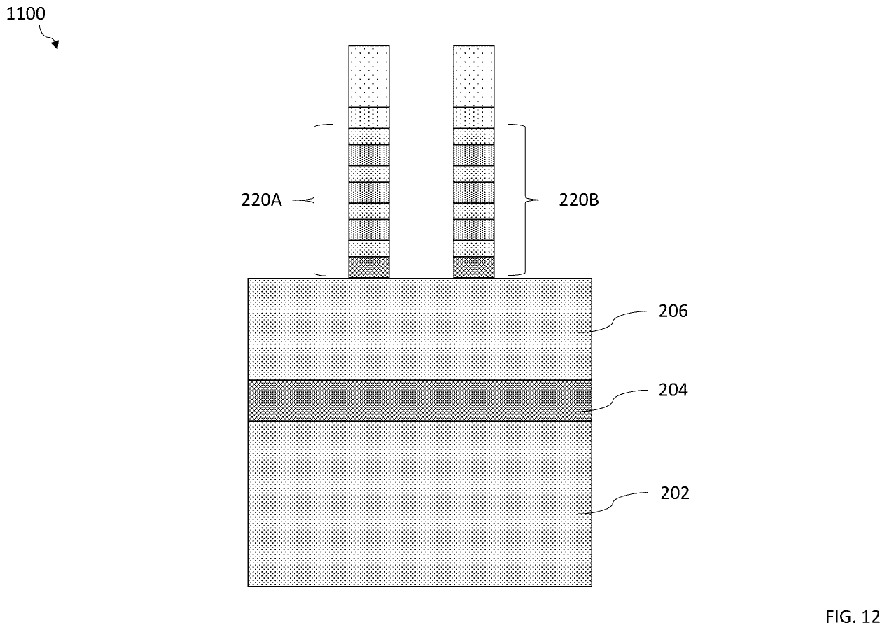

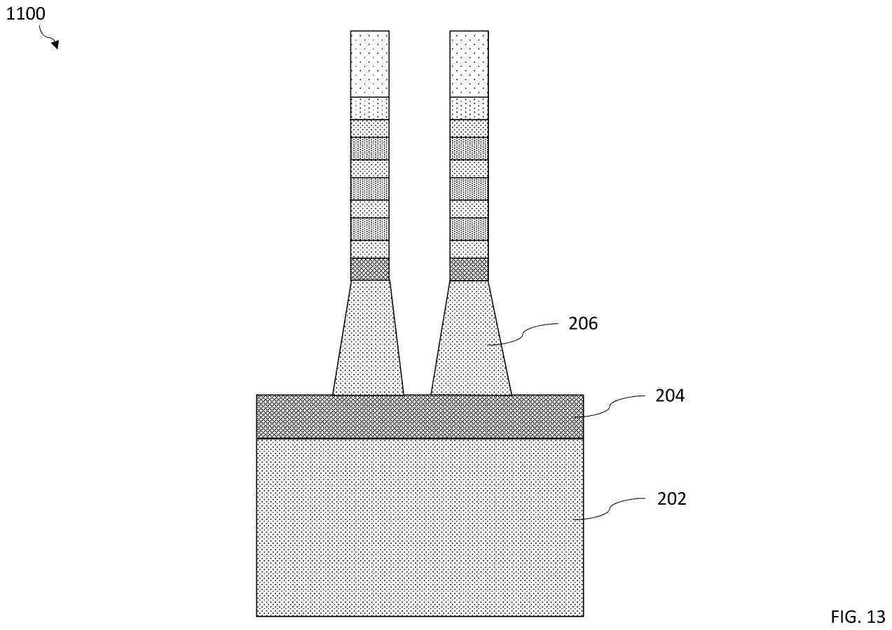

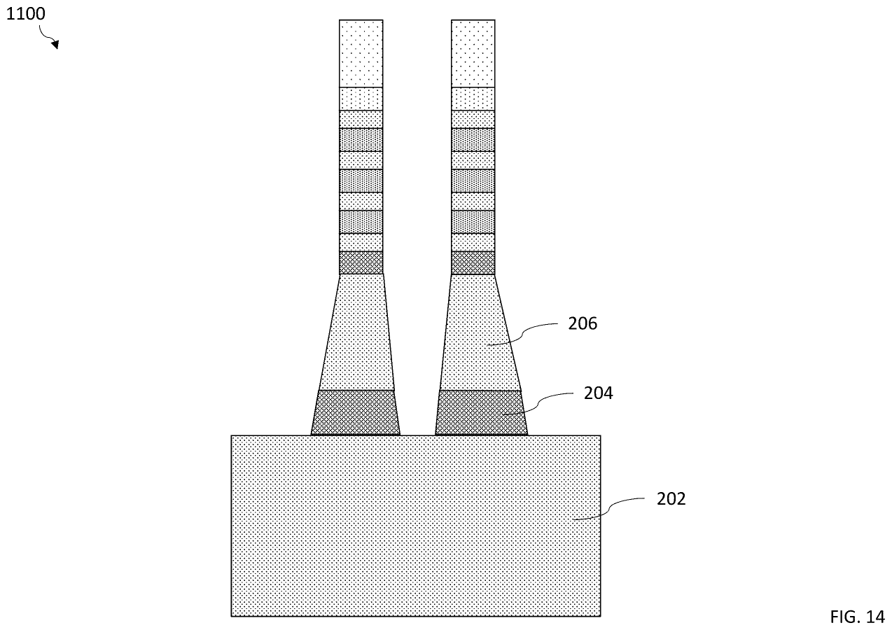

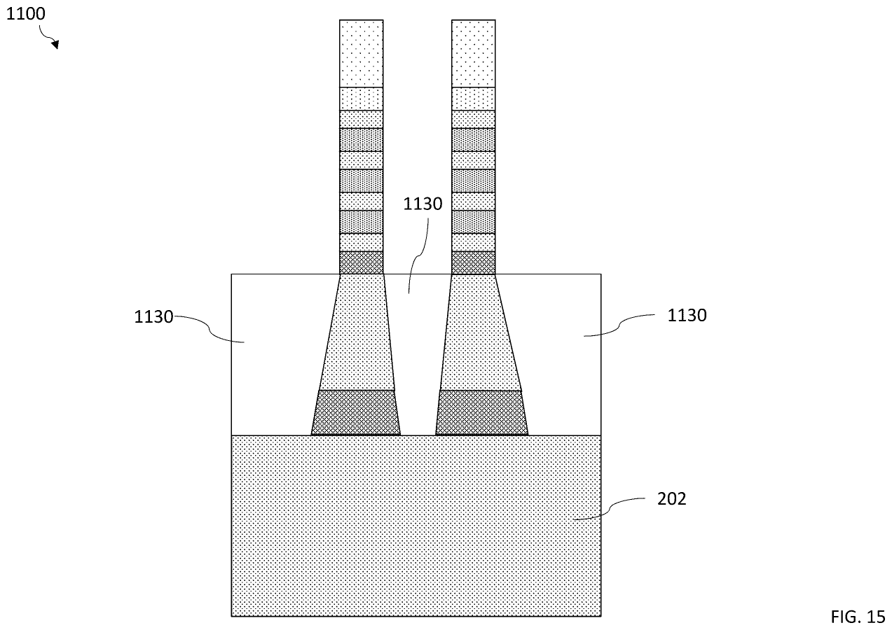

Referring next to FIG. 12, which corresponds to operation 110 (FIG. 1), the stack 1103 is patterned to form the active regions 220A-B. Referring next to FIG. 13, which corresponds to operation 112 (FIG. 1), the second semiconductor layer 206 is etched through and the corresponding etch process spontaneously stops at the first semiconductor layer 204. Referring next to FIG. 14, which corresponds to operation 114 (FIG. 1), the first semiconductor layer 204 is broken through. Referring next to FIG. 15, which corresponds to operation 118 (FIG. 1), isolation structures 1130 are formed between neighboring fin active regions 220A and 220B, or next to a single active region 220A/220B. The isolation structure 1130 is substantially similar to the isolation structure 230 (FIG. 10) except that the isolation structure 1130 does not extend into the substrate 202.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A method for forming a semiconductor device, comprising:
forming a first layer on a substrate;
forming a second layer on the first layer, wherein the substrate and the second layer have a first semiconductor material and the first layer has a second semiconductor material, and wherein an etching selectivity is present between the first semiconductor material and the second semiconductor material; and
performing a first etching process to remove a portion of the second layer until the first layer is exposed, wherein the first layer is configured as an etch stop layer for the first etching process.

2. The method of claim 1, wherein the first semiconductor material includes silicon, and the second semiconductor material includes silicon germanium.

3. The method of claim 2, wherein a molar ratio of germanium of the second semiconductor material is equal to or greater than 1/2.

4. The method of claim 1, wherein a ratio of the etching selectivity is equal to or greater than 1/100.

5. The method of claim 1, prior to performing the first etching process, further comprising:
forming a layer stack over the second layer, wherein the layer stack includes a plurality of third layers and a plurality of fourth layers alternately stacked on top of one another, and wherein the plurality of third layers each have the first semiconductor material and the plurality of fourth layers each have a third semiconductor material; and
performing a second etching process to remove a portion of the layer stack, wherein the removed portion of the layer stack is vertically aligned with the removed portion of the second layer.

6. The method of claim 5, subsequent to performing the first etching process, further comprising:
performing a third etching process to remove a portion of the first layer, wherein the removed portion of the first layer is vertically aligned with the removed portion of the second layer.

7. The method of claim 6, further comprising:
filling the removed portion of the second layer and the removed portion of the first layer with a dielectric material thereby forming an isolation structure.

8. The method of claim 7, wherein the isolation structure is configured to electrically isolate remaining portions of the layer stack that are disposed on opposite sides of the removed portion of the layer stack.

9. The method of claim 5, wherein the first semiconductor material includes silicon, the second semiconductor material includes first silicon germanium with a first germanium molar ratio, and the third semiconductor material includes second silicon germanium with a second germanium molar ratio.

10. The method of claim 9, wherein the first germanium molar ratio is substantially greater than the second germanium molar ratio.

11. A method for forming a semiconductor device, comprising:
forming, on a substrate having a first semiconductor material, a first layer having a second semiconductor material;
overlaying the first layer with a second layer having the first semiconductor material;
forming a layer stack over the second layer, wherein the layer stack includes a plurality of third layers and a plurality of fourth layers alternately stacked on top of one another, and wherein the plurality of third layers each have the first semiconductor material and the plurality of fourth layers each have a third semiconductor material;
etching a portion of the layer stack until the second layer is exposed; and
etching, through at least the etched portion of the layer stack, a portion of the second layer until the first layer is exposed.

12. The method of claim 11, further comprising:
etching, through at least the etched portion of the layer stack and the etched portion of the second layer, a portion of the first layer until a top surface of the substrate is exposed; and
filling the etched portion of the second layer and the etched portion of the first layer with a dielectric material thereby forming an isolation structure.

13. The method of claim 11, further comprising:
etching, through at least the etched portion of the layer stack and the etched portion of the second layer, a portion of the first layer and a portion of the substrate until an intermediate surface of the substrate is exposed; and
filling the etched portion of the second layer, the etched portion of the first layer, and the etched portion of the substrate with a dielectric material thereby forming an isolation structure.

14. The method of claim 11, wherein the first semiconductor material includes silicon, the second semiconductor material includes first silicon germanium with a first germanium molar ratio, and the third semiconductor material includes second silicon germanium with a second germanium molar ratio.

15. The method of claim 14, wherein the first germanium molar ratio is substantially greater than the second germanium molar ratio.

16. The method of claim 11, wherein the first layer is configured as an etch stop layer during etching the portion of the second layer.

17. The method of claim 11, wherein an etching selectivity is present between the first semiconductor material and the second semiconductor material, and wherein a ratio of the etching selectivity is equal to or greater than 1/100.

18. A method for forming a semiconductor device, comprising:
forming one or more etch stop layers having a second semiconductor material embedded in a first semiconductor material;
defining an active region of a transistor on the first semiconductor material;
etching first portions of the first semiconductor material disposed above at least one of the one or more etch stop layers and on opposite sides of the active region, respectively, until the at least one etch stop layer is exposed; and
forming an isolation structure by filling at least the etched first portions of the first semiconductor material with a dielectric material.

19. The method of claim 18, wherein the first semiconductor material includes silicon, and the second semiconductor material includes silicon germanium.

20. The method of claim 19, wherein a molar ratio of germanium of the second semiconductor material is equal to or greater than 1/2.
